(19) United States
(12) Patent Application Publication
(10) Pub. No.: US 2018/0196620 A1
(43) Pub. Date: Jul. 12, 2018

(54) DATA STORAGE DEVICE AND OPERATING METHOD THEREOF

(71) Applicant: SK hynix Inc., Gyeonggi-do (KR)

(72) Inventors: Jin Pyo KIM, Gyeonggi-do (KR); Beom Ju SHIN, Gyeonggi-do (KR)

(21) Appl. No.: 15/613,679

(22) Filed: Jun. 5, 2017

(30) Foreign Application Priority Data
Jan. 6, 2017 (KR) 10-2017-0002224

(51) Int. Cl. G06F 3/06; G11C 29/50

(52) U.S. Cl. CPC G06F 3/0659; G11C 29/50012; G06F 3/0688; G06F 3/061

(57) ABSTRACT

A data storage device includes a plurality of nonvolatile memory devices; and a controller suitable for determining a write sequence for the nonvolatile memory devices, based on respective write times of the nonvolatile memory devices, and transmitting write commands sequentially in an interleaving manner to the nonvolatile memory devices according to the write sequence.

### CROSS-REFERENCES TO RELATED APPLICATION

The present application claims priority under 35 U.S.C. § 119(a) to Korean application number 10-2017-0002224, flied on Jan. 6, 2017, in the Korean Intellectual Property Office, which is incorporated herein by reference in its entirety.

### BACKGROUND

### 1. Technical Field

Various embodiments generally relate to a data storage device, and, more particularly, to a data storage device including a nonvolatile memory device.

### 2. Related Art

Data storage devices store data received from an external device in response to a write request. Data storage devices may also provide stored data to an external device in response to a read request. Examples of external devices that use data storage devices include computers, digital cameras, cellular phones and the like. Data storage devices may be embedded in an external device during manufacturing of the external devices or may be fabricated separately and then connected afterwards to an external device.

### SUMMARY

Various embodiments are directed to provide a data storage device including a controller and a plurality of nonvolatile memory devices. The data storage device exhibits an improved interleaving operation speed.

According to an embodiment, a data storage device is provided, the data storage device including: a plurality of nonvolatile memory devices; and a controller suitable for determining a write sequence for the nonvolatile memory devices, based on respective write times of the nonvolatile memory devices, and transmitting write commands sequentially in an interleaving manner to the nonvolatile memory devices according to the write sequence.

According to another embodiment, a method for operating a data storage device is provided, the method including: determining a write sequence for a plurality of nonvolatile memory devices, based on respective write times of the nonvolatile memory devices; and transmitting write commands sequentially in an interleaving manner to the nonvolatile memory devices according to the write sequence.

In yet another embodiment, a data storage device may include: a plurality of nonvolatile memory devices; and a controller suitable for transmitting a write command earliest to a nonvolatile memory device which has a longest write time, among the nonvolatile memory devices, when storing data in the nonvolatile memory devices in an interleaving scheme.

### BRIEF DESCRIPTION OF THE DRAWINGS

The above and other features and advantages of the present invention will become more apparent to those skilled in the art to which the present invention belongs by describing various embodiments thereof with reference to the attached drawings in which:

FIG. 1 is a block diagram illustrating a data storage device in accordance with an embodiment of the present invention.

FIG. 2 is a diagram illustrating a method for operating the data storage device of FIG. 1.

FIG. 3 is a diagram explaining an operating method of a scheme different from the embodiment of the present invention.

FIG. 4 is a flow chart of a method for operating the data storage device of FIG. 1.

FIG. 5 is a block diagram illustrating a solid state drive (SSD) in accordance with an embodiment of the present invention.

FIG. 6 is a block diagram illustrating a data processing system to which a data storage device is applied, in accordance an embodiment of the present invention.

### DETAILED DESCRIPTION

Hereinafter, a data storage device and an operating method thereof according to the present invention will be described with reference to the accompanying drawings through exemplary embodiments of the present invention. The present invention may, however, be embodied in different forms and should not be construed as being limited to the embodiments set forth herein. Rather, these embodiments are provided to describe the present invention in detail to the extent that a person skilled in the art to which the invention pertains can enforce the technical concepts of the present invention.

It is to be understood that embodiments of the present invention are not limited to the particulars shown in the drawings, that the drawings are not necessarily to scale, and, in some instances, proportions may have been exaggerated in order to more clearly depict certain features of the invention. While particular terminology is used, it is to be appreciated that the terminology used is for describing particular embodiments only and is not intended to limit the scope of the present invention.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The phrase “at least one of . . . and . . . ,” when used herein with a list of items, means a single item from the list or any combination of items in the list. For example, “at least one of A, B, and C” means, only A, or only B, or only C, or any combination of A, B, and C.

The term “or” as used herein means either one of two or more alternatives but not both nor any combinations thereof.

As used herein, singular forms are intended to include the plural forms as well, unless the context clearly indicates otherwise. It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, an element also referred to as a feature described in connection with one embodiment may be used singly or in combination with other elements of another embodiment, unless specifically indicated otherwise.

Hereinafter, the various embodiments of the present invention will be described in detail with reference to the attached drawings.

FIG. 1 is a block diagram illustrating a data storage device 10 in accordance with an embodiment of the present invention.

The data storage device 10 may be configured to store data provided from an external device, in response to a write request from the external device. Also, the data storage device 10 may be configured to provide stored data to the external device, in response to a read request from the external device.

The data storage device 10 may be configured as a Personal Computer Memory Card International Association (PCMCIA) card, a Compact Flash (CF) card, a smart media card, a memory stick, various multimedia cards (e.g., MMC, eMMC, RS-MMC, and MMC-Micro), various secure digital cards (e.g., SD, Mini-SD, and Micro-SD), a Universal Flash Storage (UFS), a Solid State Drive (SSD) and the like.

The data storage device 10 may include a controller 100 and first to fourth nonvolatile memory devices MEM1 to MEM4.

The controller 100 may control general operations of the data storage device 10. The controller 100 may store data in the first to fourth nonvolatile memory devices MEM1 to MEM4 in response to write requests transmitted from the external device, and may read data stored in the first to fourth nonvolatile memory devices MEM1 to MEM4 and output the read data to the external device in response to read requests transmitted from the external device. In particular, the controller 100 may access the first to fourth nonvolatile memory devices MEM1 to MEM4 in an interleaving scheme. The controller 100 may include a write sequence determination unit 110 for determining to an effective interleaving access to the first to fourth nonvolatile memory devices MEM1 to MEM4 that improves the operation a speed of the data storage device.

The write sequence determination unit 110 may determine a write sequence for the first to fourth nonvolatile memory devices MEM1 to MEM4, based on respective write times of the first to fourth nonvolatile memory devices MEM1 to MEM4. A write time for a nonvolatile memory device among the nonvolatile memory devices MEM1 to MEM4 is the time it takes to perform a write operation to the nonvolatile memory device. Each of the first to fourth nonvolatile memory devices MEM1 to MEM4 may have a different write time. The first to fourth nonvolatile memory devices MEM1 to MEM4 may have a different write time for a number of reasons. For example, the first to fourth nonvolatile memory devices MEM1 to MEM4 may be of different type. Or the first to fourth nonvolatile memory devices MEM1 to MEM4 may be of the same type but may have different write times due to manufacturing variances, wear leveling differences, or their position within the configuration of the data storage device to name a few.

A write sequence may be determined in an order of decreasing write times i.e., the first to fourth nonvolatile memory devices MEM1 to MEM4 may be arranged in a write sequence starting with the nonvolatile memory device having the longest write time and finishing with the nonvolatile memory device having the shortest write time.

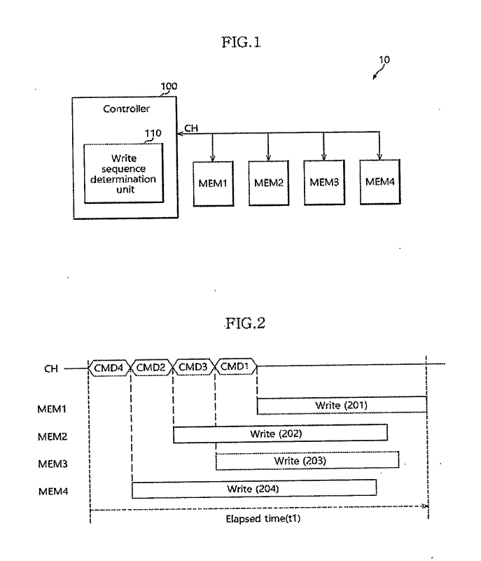

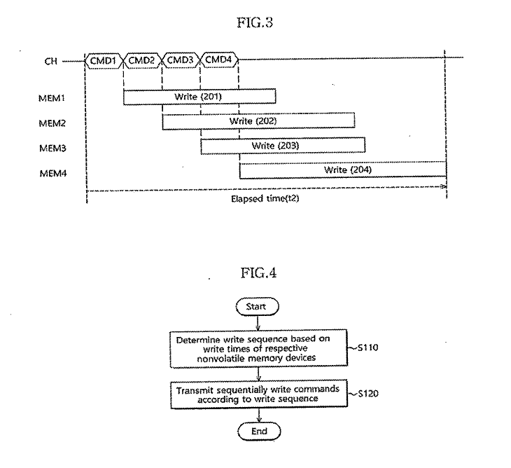

The controller 100 may store data in the first to fourth nonvolatile memory devices MEM1 to MEM4 according to the interleaving scheme in response to the write sequence determined by the write sequence determination unit 110. That is, the controller 100 may transmit sequentially write commands to the first to fourth nonvolatile memory devices MEM1 to MEM4 according to the write sequence. The first to fourth nonvolatile memory devices MEM1 to MEM4 may perform write operations in parallel in response to the write commands according to an interleaving scheme following a write sequence which is based on a decreasing write time order, i.e., a nonvolatile memory device having the longest write time may start the write operation first (i.e., at an earliest time) and a nonvolatile memory device having the shortest write time may start the write operation last (i.e. at a latest time), among the first to fourth nonvolatile memory devices MEM1 to MEM4. As a result, an elapsed time until all the write operations of the first to fourth nonvolatile memory devices MEM1 to MEM4 are completed may be shortened in comparison with a case of determining a write sequence without considering the individual write times of the first to fourth nonvolatile memory devices. A detailed operating method will be described later with reference to FIG. 2.

Meanwhile, the write times of the first to fourth nonvolatile memory devices MEM1 to MEM4 may be measured and determined at a manufacturing stage, and be stored in respective storage regions (not shown) of the first to fourth nonvolatile memory devices MEM1 to MEM4. The write sequence determination unit 110 may determine the write sequence by reading the write times stored in the respective storage regions of the first to fourth nonvolatile memory devices MEM1 to MEM4. The write sequence determination unit 110 may determine the write sequence by reading the write times from the respective storage regions each time power is turned on. The determined write sequence may be used after being stored in separate regions of the first to fourth nonvolatile memory devices MEM1 to MEM4.

According to an embodiment, the write sequence determination unit 110 may measure write times by testing write operations for the respective first to fourth nonvolatile memory devices MEM1 to MEM4, and may newly determine a write sequence based on the measured write times. This way, the write sequence determination unit 110 may reset the write sequence to reflect performance degradation due to wear of the first to fourth nonvolatile memory devices MEM1 to MEM4. In an embodiment, the write sequence determination unit 110 may periodically determine a write sequence based on newly measured write times at a predetermined time interval. The predetermined time interval may be preset, for example, based on an expected wear rate of the nonvolatile memory devices. In an embodiment, the time interval between two successive operations of measuring the write times (and resetting the write sequence) may vary based on the wear rates of the respective first to fourth nonvolatile memory devices MEM1 to MEM4. For example, a wear rate of each of the first to fourth nonvolatile memory devices MEM1 to MEM4 may be proportional to, for example, an erase count of an entire memory region of each nonvolatile memory device or an erase count of a fixed partial memory region of each nonvolatile memory device. For example, the write sequence determination unit 110 may measure the write times and reset the write sequence, each time an erase count of each of the first to fourth nonvolatile memory devices MEM1 to MEM4 reaches each of predetermined values, for example, multiples of 1000.

The first to fourth nonvolatile memory devices MEM1 to MEM4 may share a transmission line, i.e., a channel CH. Each of the first to fourth nonvolatile memory devices MEM1 to MEM4 may receive various control signals including a write command and data through the channel CH from the controller 100, and perform internal operations including a write operation. When the first to fourth nonvolatile memory devices MEM1 to MEM4 are accessed in the interleaving scheme, they may perform internal operations in parallel.

A nonvolatile memory device may include a flash memory, such as a NAND flash or a NOR flash, a Ferroelectrics Random Access Memory (FeRAM), a Phase-Change Random Access Memory (PCRAM), a Magnetoresistive Random Access Memory (MRAM), a Resistive Random Access Memory (ReRAM), and the like.

While FIG. 1 illustrates four nonvolatile memory devices MEM1 to MEM4 which share one channel CH, it is to be noted that the number of nonvolatile memory devices which share the channel CH is not limited thereto. Moreover, while FIG. 1 illustrates that the data storage device 10 includes one channel CH, it is to be noted that the number of channels included in the data storage device 10 is not limited thereto. When the data storage device 10 includes a plurality of channels, the controller 100 may determine write sequences for each of the respective channels according to the above-described method, and store data in the first to fourth nonvolatile memory devices MEM1 to MEM4 through the respective channels in the interleaving scheme according to the determined write sequences.

FIG. 2 is a diagram illustrating a method for operating the data storage device 10 of FIG. 1.

First, when write times of the first to fourth nonvolatile memory devices MEM1 to MEM4 are measured as shown in TABLE 1, the write sequence determination unit 110 may determine a write sequence in order of decreasing write times, that is, in the sequence of the fourth nonvolatile memory device MEM4, the second nonvolatile memory device MEM2, the third nonvolatile memory device MEM3 and the first nonvolatile memory device MEM1. In TABLE 1, a write turn may mean an earlier turn as the value thereof is smaller.

TABLE 1

| | | Write |
|---|---|---|
| | | sequence |
| Nonvolatile memory device | Write time | turn |
| MEM1 | 800 μs | 4 |
| MEM2 | 1000 μs | 2 |
| MEM3 | 900 μs | 3 |
| MEM4 | 1200 μs | 1 |

Accordingly, referring to FIG. 2, when storing data in the first to fourth nonvolatile memory devices MEM1 to MEM4 in the interleaving scheme, the controller 100 may transmit sequentially write commands CMD4, CMD2, CMD3 and CMD1 including data, to the fourth nonvolatile memory device MEM4, the second nonvolatile memory device MEM2, the third nonvolatile memory device MEM3 and the first nonvolatile memory device MEM1, through the channel CH, according to the write sequence.

As a result, the fourth nonvolatile memory device MEM4 having the longest write time may start earliest a write operation 204 in response to the write command CMD4. Subsequently, the second nonvolatile memory device MEM2, the third nonvolatile memory device MEM3 and the first nonvolatile memory device MEM1 may perform sequentially write operations 202, 203 and 201 in response to the write commands CMD2, CMD3 and CMD1, respectively. An elapsed time t1 until all the first to fourth nonvolatile memory devices MEM1 to MEM4 complete the write operations is as illustrated.

FIG. 3 is a diagram illustrating an operating method of a scheme different from the embodiment of the present invention.

Referring to FIG. 3, the write commands CMD1 to CMD4 may be transmitted sequentially, for example, to the first nonvolatile memory device MEM1 to the fourth nonvolatile memory device MEM4, according to a write sequence that does not consider the write times of the first to fourth nonvolatile memory devices MEM1 to MEM4. In this case, an elapsed time t2 until all the first to fourth nonvolatile memory devices MEM1 to MEM4 complete write operations 201 to 204 may be determined by a write operation 204 that is completed latest. However, because the fourth nonvolatile memory device MEM4 having a longest write time starts a write operation latest, the elapsed time t2 may be longer than the elapsed time t1 in FIG. 2. That is, in the case where the write commands CMD1 to CMD4 are transmitted according to, for example, physical positions, that is, in order of position close to the controller 100, without considering write times of the first to fourth nonvolatile memory devices MEM1 to MEM4, it may be difficult to expect optimal interleaving performance.

However, according to the embodiment, attributable to the write sequence based on the write times of the first to fourth nonvolatile memory devices MEM1 to MEM4, it is possible to provide a faster interleaving operation.

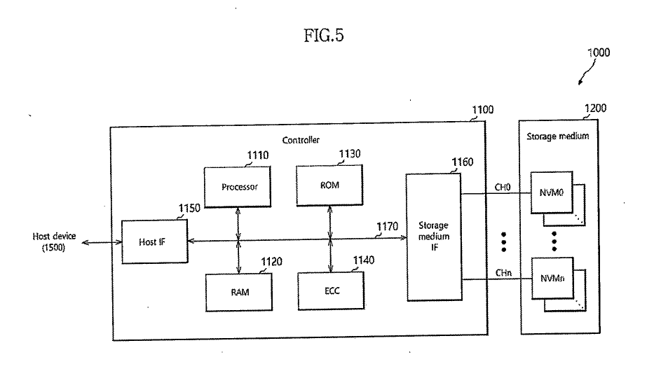

FIG. 4 is a flow chart of a method for operating the data storage device 10 of FIG. 1. FIG. 4 illustrates a method in which the controller 100 stores data in the first to fourth nonvolatile memory devices MEM1 to MEM4 in the interleaving scheme of the present invention taking into account the write times of the nonvolatile memory devices.

At step S110, the controller 100 may determine a write sequence for the first to fourth nonvolatile memory devices MEM1 to MEM4, based on the respective write times of the first to fourth nonvolatile memory devices MEM1 to MEM4. The write sequence may be determined in order of decreasing write times, for the first to fourth nonvolatile memory devices MEM1 to MEM4, as explained above.

At step S120, the controller 100 may transmit sequentially write commands to the first to fourth nonvolatile memory devices MEM1 to MEM4 according to the write sequence. The first to fourth nonvolatile memory devices MEM1 to MEM4 may perform write operations in parallel in response to the write commands while a nonvolatile memory device having a longest write time may start earliest the write operation. Thus, an elapsed time until all the write operations of the first to fourth nonvolatile memory devices MEM1 to MEM4 are completed may be shortened in comparison with the case of determining a write sequence without considering write times.

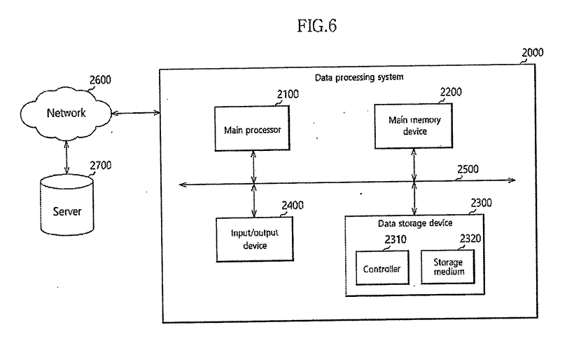

FIG. 5 is a block diagram illustrating a solid state drive (SSD) 1000 in accordance with an embodiment of the present invention.

The SSD 1000 may include a controller 1100 and a storage medium 1200.

The controller 1100 may control data exchange between a host device 1500 and the storage medium 1200. The controller 1100 may include a processor 1110, a random access memory (RAM) 1120, a read only memory (ROM) 1130, an error correction code (ECC) unit 1140, a host interface 1150 and a storage medium interface 1160, which are coupled through an internal bus 1170.

The controller 1100 may operate substantially similarly to the controller 100 shown in FIG. 1. The controller 1100 may determine write sequences based on write times of nonvolatile memory devices, for respective channels CH0 to CHn. The controller 1100 may store data in the storage medium 1200 in an interleaving scheme according to the determined write sequences, for respective channels CH0 to CHn.

The processor 1110 may control general operations of the controller 1100. The processor 1110 may store data in the storage medium 1200 and read stored data from the storage medium 1200, according to data processing requests from the host device 1500. In order to efficiently manage the storage medium 1200, the processor 1110 may also control internal operations of the SSD 1000 such as a merge operation, a wear leveling operation, and so forth.

The RAM 1120 may store programs and program data to be used by the processor 1110. The RAM 1120 may temporarily store data transmitted from the host interface 1150 before transferring it to the storage medium 1200, and may temporarily store data transmitted from the storage medium 1200 before transferring it to the host device 1500.

The ROM 1130 may store program codes to be read by the processor 1110. The program codes may include commands to be processed by the processor 1110, for the processor 1110 to control the internal units of the controller 1100.

The ECC unit 1140 may encode data to be stored in the storage medium 1200, and may decode data read from the storage medium 1200. The ECC unit 1140 may detect and correct an error occurred in data, according to an ECC algorithm.

The host interface 1150 may exchange data processing requests, data, etc. with the host device 1500.

The storage medium interface 1160 may transmit control signals and data to the storage medium 1200. The storage medium interface 1160 may receive data from the storage medium 1200. The storage medium interface 1160 may be coupled with the storage medium 1200 through a plurality of channels CH0 to CHn. Any suitable storage medium interface may be used.

The storage medium 1200 may include a plurality of nonvolatile memory devices NVM0 to NVMn. Each of the plurality of nonvolatile memory devices NVM0 to NVMn may perform a write operation and a read operation according to control of the controller 1100.

FIG. 6 is a block diagram illustrating a data processing system 2000 to which the data storage device 10 of FIG. 1 is applied, in accordance with an embodiment of the present invention.

The data processing system 2000 may include a computer, a laptop, a netbook, a smart phone, a digital TV, a digital camera, a navigator, etc. The data processing system 2000 may include a main processor 2100, a main memory device 2200, a data storage device 2300, and an input/output device 2400. The internal units of the data processing system 2000 may exchange data, control signals, etc. through a system bus 2500.

The main processor 2100 may control general operations of the data processing system 2000. The main processor 2100 may be a central processing unit, for example, such as a microprocessor. The main processor 2100 may execute softwares such as an operating system, an application, a device driver, and so forth, on the main memory device 2200.

The main memory device 2200 may store programs and program data to be used by the main processor 2100. The main memory device 2200 may temporarily store data to be transmitted to the data storage device 2300 and the input/output device 2400.

The data storage device 2300 may include a controller 2310 and a storage medium 2320. The data storage device 2300 may be configured and operate substantially similarly to the data storage device 10 of FIG. 1.

The input/output device 2400 may include a keyboard, a scanner, a touch screen, a screen monitor, a printer, a mouse, or the like, capable of exchanging data with a user, such as receiving a command for controlling the data processing system 2000 from the user or providing a processed result to the user.

According to an embodiment, the data processing system 2000 may communicate with at least one server 2700 through a network 2600 such as a local area network (LAN), a wide area network (WAN), a wireless network, and so on. The data processing system 2000 may include a network interface (not shown) to access the network 2600.

While various embodiments have been described above, it will be understood to those skilled in the art that the embodiments described are examples only. Accordingly, the data storage device and the operating method thereof described herein should not be limited to the described embodiments. It will be apparent to those skilled in the art to which the present invention pertains that various other changes and modifications may be made without departing from the spirit and scope of the invention as defined in the following claims.

What is claimed is:

1. A data storage device comprising:
a plurality of nonvolatile memory devices; and
a controller suitable for determining a write sequence for the nonvolatile memory devices, based on respective write times of the nonvolatile memory devices, and transmitting write commands sequentially in an interleaving manner to the nonvolatile memory devices according to the write sequence.

2. The data storage device according to claim 1, wherein the write sequence is determined in order of decreasing write times.

3. The data storage device according to claim 1, wherein the nonvolatile memory devices perform write operations in response to the write commands in parallel according to the write sequence.

4. The data storage device according to claim 3, wherein a nonvolatile memory device having a longest write time starts the write operation earliest, among the nonvolatile memory devices.

5. The data storage device according to claim 1, wherein the controller measures the write times by testing write operations for the respective nonvolatile memory devices.

6. The data storage device according to claim 1, wherein the controller measures periodically the write times of the nonvolatile memory devices at time intervals which are based on the wear rates of the respective nonvolatile memory devices.

7. The data storage device according to claim 1, wherein the nonvolatile memory devices share a transmission line through which the write commands are transmitted.

8. A method for operating a data storage device, comprising:
determining a write sequence for a plurality of nonvolatile memory devices, based on respective write times of the nonvolatile memory devices; and
transmitting write commands sequentially in an interleaving manner to the nonvolatile memory devices according to the write sequence.

9. The method according to claim 8, wherein the write sequence is determined in order of decreasing write times.

10. The method according to claim 8, wherein the nonvolatile memory devices perform write operations in parallel in response to the write commands.

11. The method according to claim 10, wherein a nonvolatile memory device having a longest write time starts the write operation earliest, among the nonvolatile memory devices.

12. The method according to claim 8, further comprising:
measuring the write times by testing write operations for the respective nonvolatile memory devices.

13. The method according to claim 8, further comprising:
measuring periodically the write times of the respective nonvolatile memory devices at time intervals which are based on wear rates of the respective nonvolatile memory devices.

14. The method according to claim 8, wherein the nonvolatile memory devices share a transmission line through which the write commands are transmitted.

15. A data storage device comprising:
a plurality of nonvolatile memory devices; and
a controller suitable for transmitting a write command earliest to a nonvolatile memory device which has a longest write time, among the nonvolatile memory devices, when storing data in the nonvolatile memory devices in an interleaving scheme.

16. The data storage device according to claim 15, wherein the controller transmits write commands sequentially to the nonvolatile memory devices in order of decreasing write times in the nonvolatile memory devices.

17. The data storage device according to claim 16, wherein the nonvolatile memory devices perform write operations in parallel in response to the write commands.

18. The data storage device according to claim 15, wherein the controller measures the write times by testing write operations for the respective nonvolatile memory devices.

19. The data storage device according to claim 15, wherein the controller measures periodically the write times of the nonvolatile memory devices at time intervals which are based on wear rates of the respective nonvolatile memory devices.

20. The data storage device according to claim 15, wherein the nonvolatile memory devices share a transmission line through which the write commands are transmitted.
